(19) United States
(12) Patent Application Publication
(10) Pub. No.: US 2002/0182893 A1
(43) Pub. Date: Dec. 5, 2002

(54) Oxidation of silicon nitride films in semiconductor devices

(75) Inventors: Arne W. Ballantine, Round Lake, NY (US); Johnathan E. Faltermeier, LaGrangeville, NY (US); Philip L. Flaitz, Newburgh, NY (US); Jeffrey D. Gilbert, South Burlington, VT (US); Oleg Gluschenkov, Wappingers Falls, NY (US); Carol J. Heenan, LaGrangeville, NY (US); Rajarao Jammy, Wappingers Falls, NY (US); Ryota Katsumada, Isogo-ku (JP)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NJ

(21) Appl. No.: 09/874,144

(22) Filed: Jun. 5, 2001

(51) Int. Cl. H01L 21/31; H01L 21/469; H01L 21/26; H01L 21/324; H01L 21/42; H01L 21/477

(52) U.S. Cl. 438/795; 438/787

(57) ABSTRACT

Disclosed is a method to convert a stable silicon nitride film into a stable silicon oxide film with a low content of residual nitrogen in the resulting silicon oxide film. This is an unexpected and unique property of the in situ steam generation process since both silicon nitride and silicon oxide materials are chemically very stable compounds. Application of the claimed method to the art of microelectronic device fabrication, such as fabrication of on-chip dielectric capacitors and metal insulator semiconductor field effect transistors, is also disclosed.

### BACKGROUND OF THE INVENTION

The present invention relates generally to semiconductor devices and, in particular, to a method for the oxidation of silicon nitride films in microelectronic devices.

The oxidation of silicon nitride is commonly used in the fabrication of microelectronic devices. Typical applications include the oxidation of silicon nitride to form a dielectric for high-density dynamic random access memory (DRAM), as a gate dielectric, and to form the dielectric layer in stacked capacitor elements.

There are a number of methods proposed by others which use the oxidation of silicon nitride films in the manufacture of microelectronic devices.

Geissler et al. U.S. Pat. No. 5,434,109, the disclosure of which is incorporated by reference herein, discloses that oxidized silicon nitride films can be used for DRAM memory cell fabrication, gate dielectric formation for Metal Oxide Semiconductor (MOS) transistors, and fabrication of other microelectronic structures. Geissler discloses a method of oxidizing silicon nitride films in the mixture of an oxidizing agent, such as O2, and a fluorine-bearing gaseous compound, such as NF3. Geissler teaches that a source of fluorine radicals is needed in order to weaken the bond strength in the silicon nitride compound and allow for a fast conversion of silicon nitride into silicon oxide. Geissler also discloses that there is a competition between oxidation of silicon nitride and the etching of the produced silicon oxide film which may limit the final thickness of the oxide film.

Thakur et al. U.S. Pat. No. 5,966,595, the disclosure of which is incorporated by reference herein, discloses a method of silicon nitride oxidation in the ozone gas excited by an ultraviolet radiation. Thakur also discloses how such an oxidized nitride layer can be used as a dielectric for on-chip capacitors such as DRAM capacitors.

Hong et al. U.S. Pat. No. 5,504,021, the disclosure of which is incorporated by reference herein, compares different methods of oxidation of thin oxide/nitride stacks for the purpose of creating a thin oxide/nitride/oxide dielectric stack to be used in high-density DRAM capacitors. Hong discloses that only low pressure (0.01 Torr to 76 Torr) dry oxidation results in the growth of an oxide layer on the surface of the initial oxide/nitride stack while both wet and dry oxidation conducted at atmospheric pressure produces an oxide growth underneath the nitride layer. Despite the long duration of the oxidation process (10 to 60 minutes) in this case the maximum thickness of the grown oxide was lower than 30 Å.

Murata et al. U.S. Pat. No. 5,504,029 and Schuegraf et al. U.S. Pat. No. 5,624,865, the disclosures of which are incorporated by reference herein, disclose a method of silicon nitride oxidation using a high pressure oxidizing ambient. High concentration of oxidizing species increase the rate of conversion of silicon nitride to silicon oxide thereby growing a surface layer of silicon oxide at reduced time or temperature. Nevertheless, the rate of high pressure oxidation of nitride is still low compared to the fluorine-enhanced method described in Geissler, U.S. Pat. No. 5,434,109.

Tobin et al. U.S. Pat. No. 5,972,804, the disclosure of which is incorporated by reference herein, discloses a method to form a thin silicon nitride layer with a specifically engineered profile of oxygen and nitrogen in the film. Tobin discloses that after formation of a thin silicon nitride layer, either by thermal nitridation of silicon or by low pressure chemical vapor deposition (LPCVD), optional in-situ oxidation steps may be needed to tailor a specific profile of oxygen and nitrogen in the film. The method is directed toward the reduction of oxygen in the dielectric stack and selective introduction of oxygen close to the semiconductor/dielectric interface. To reduce incorporation of oxygen into the silicon nitride the oxidation step is performed in-situ by exposing the nitride layer to a nitrous oxide ambient. This method allows for the engineering of thin layers of silicon nitride with low oxygen content.

Yamada U.S. Pat. No. 5,023,683, the disclosure of which is incorporated by reference herein, discloses a vertical stack-type capacitor which may employ a silicon nitride-silicon oxide stack as its dielectric. Yamada also discloses a conventional method of forming such a dielectric stack. A thin silicon nitride layer is oxidized in a steam atmosphere. This is one of the conventional methods of silicon nitride oxidation which requires a relatively large thermal budget, and may produce silicon oxide with a relatively large nitrogen content.

Gronet et al. U.S. Pat. No. 6,037,273, the disclosure of which is incorporated by reference herein, discloses an apparatus to carry out an in-situ steam generation oxidation technique. Gronet discloses that the in-situ steam generation rapid thermal processor is well suited for high volume semiconductor manufacturing due to a superior temperature uniformity, fast temperature ramps, high throughput, and acceptable safety record. Gronet discloses that a substrate can be placed in such a reactor and then oxidized using the in-situ generated steam. Gronet discloses a fast oxidation of a substrate having a silicon layer. Gronet, however, does not teach that an in-situ generated water vapor ambient results in a fast conversion of a chemically very stable silicon nitride layer into a substantially pure silicon oxide layer at relatively low temperature. In fact, other prior art teaches away from this. Indeed, in any of the cited disclosures some form of excitation is needed to convert silicon nitride to a substantially pure silicon oxide at a lower temperature, such as addition of fluorine radicals in Geissler (above) or UV-excited ozone gas in Thakur (above) or the high pressure in Murata (above).

Notwithstanding the prior art there remains a need for a versatile method for the continuous conversion of silicon nitride into substantially nitrogen-free silicon oxide.

Thus, a purpose of the present invention is to provide a method to continuously convert a stable silicon nitride film into a substantially nitrogen-free stable silicon oxide film.

It is another purpose of the present invention to provide a method to selectively mask a silicon nitride layer with a silicon oxide layer.

It is another purpose of the present invention to provide a method to allow the use of an oxide-etching hydro-fluoric acid based wet chemistry for nitride removal.

It is another purpose of the present invention to provide a method whereby a nitrided silicon surface can be oxidized directly without first stripping the silicon oxide/nitride layer.

It is another purpose of the present invention to provide an improved method for the fabrication of oxide/nitride/oxide and nitride/oxide on-chip dielectric capacitors and metal insulator semiconductor field effect transistors.

These and other purposes of the present invention will become more apparent after referring to the following description considered in conjunction with the accompanying drawings.

### BRIEF SUMMARY OF THE INVENTION

The inventors have discovered that using a method of rapid thermal oxidation (RTO), known in the prior art as In-Situ Steam Generation (ISSG), one can convert a stable silicon nitride film into a stable silicon oxide film with a low content of residual nitrogen in the resulting silicon oxide film such that the resulting silicon oxide film is substantially nitrogen-free. This is an unexpected and unique property of the ISSG process since both silicon nitride and silicon oxide materials are chemically very stable compounds. Application of the claimed method to the art of microelectronic device fabrication is also disclosed.

A first embodiment of the invention is a method where a silicon nitride film is at least partially converted to a silicon oxide film, the method comprising the steps of providing a silicon nitride film; providing a low pressure environment for the silicon nitride film of between about 100 Torr to about 0.1 Torr; introducing hydrogen and oxygen into the low pressure environment; maintaining the low pressure environment at a temperature of about 600° C. to about 1200° C. for a predetermined amount of time; where the hydrogen and oxygen reacts in the low pressure environment to rapidly oxidize the silicon nitride film and convert at least partially the silicon nitride film to a silicon oxide film.

Another embodiment is a method to create a hard mask silicon oxide structure by depositing a resist layer onto the silicon oxide film; patterning the resist layer to form a resist mask; etching the silicon oxide film exposed by the resist mask and removing the resist mask to result in a hard mask silicon oxide structure.

Another embodiment of the invention is a method of stripping a nitride layer with a wet chemistry designed for silicon oxide etching, the method comprising the steps of providing a substrate having a silicon nitride film; providing a low pressure environment for the silicon nitride film of between about 100 Torr to about 0.1 Torr; introducing hydrogen and oxygen into the low pressure environment; maintaining the low pressure environment at a temperature of about 600° C. to about 1200° C. for a predetermined amount of time; wherein the hydrogen and oxygen reacts in the low pressure environment to rapidly oxidize the silicon nitride film and at least partially convert the silicon nitride film to a silicon oxide film; stripping the silicon oxide film with a wet chemistry designed for silicon oxide etching.

Another embodiment is a method for fabricating a nitride/oxide on-chip dielectric capacitor, the method comprising the steps of: providing a first electrode with a silicon nitride film having an exposed portion, providing a low pressure environment for the silicon nitride film of between about 100 Torr to about 0.1 Torr; introducing hydrogen and oxygen into the low pressure environment; maintaining the low pressure environment at a temperature of about 600° C. to about 1200° C. for a predetermined amount of time; wherein the hydrogen and oxygen reacts in the low pressure environment to rapidly oxidize the silicon nitride film and at least partially convert the exposed portion of the silicon nitride film to a silicon oxide film; forming a second electrode on the silicon oxide film to create a nitride-oxide dielectric capacitor.

Another embodiment is a method for fabricating an oxide/nitride/oxide on-chip dielectric capacitor, the method comprising the steps of: providing a first electrode with a silicon oxide film on the first electrode; providing a silicon nitride film having an exposed portion on the silicon oxide film; providing a low pressure environment for the silicon nitride film of between about 100 Torr to about 0.1 Torr; introducing hydrogen and oxygen into the low pressure environment; maintaining the low pressure environment at a temperature of about 600° C. to about 1200° C. for a predetermined amount of time; wherein the hydrogen and oxygen reacts in the low pressure environment to rapidly oxidize the silicon nitride film and convert the exposed portion of the silicon nitride film to a second silicon oxide film; forming a second electrode on the second silicon oxide film to create an oxide/nitride/oxide dielectric capacitor.

Another embodiment is a method for fabricating a nitride/oxide gate dielectric of a metal insulator semiconductor field effect transistor, the method comprising the steps of: providing a semiconducting film with a silicon nitride film having an exposed portion; providing a low pressure environment for the silicon nitride film of between about 100 Torr to about 0.1 Torr; introducing hydrogen and oxygen into the low pressure environment; maintaining the low pressure environment at a temperature of about 600° C. to about 1200° C. for a predetermined amount of time; wherein the hydrogen and oxygen reacts in the low pressure environment to rapidly oxidize the silicon nitride film and convert the exposed portion of the silicon nitride film to a silicon oxide film; forming a gate electrode on the silicon oxide film to create a nitride-oxide gate dielectric of a metal insulator semiconductor field effect transistor.

Another embodiment is a method for fabricating an oxide/nitride/oxide gate dielectric of a metal insulator semiconductor field effect transistor, the method comprising the steps of: providing a semiconducting film having a silicon oxide film; providing a silicon nitride film having an exposed portion on the silicon oxide film; providing a low pressure environment for the silicon nitride film of between about 100 Torr to about 0.1 Torr; introducing hydrogen and oxygen into the low pressure environment; maintaining the low pressure environment at a temperature of about 600° C. to about 1200° C. for a predetermined amount of time; wherein the hydrogen and oxygen reacts in the low pressure environment to rapidly oxidize the silicon nitride film and convert the exposed portion of the silicon nitride film to a second silicon oxide film; forming a gate electrode on the second silicon oxide film to create an oxide/nitride/oxide gate dielectric of a metal insulator semiconductor field effect transistor.

### BRIEF DESCRIPTION OF THE DRAWINGS

The features of the invention believed to be novel and the elements characteristic of the invention are set forth with particularity in the appended claims. The invention itself, however, both as to organization and method of operation, may best be understood by reference to the detailed description which follows taken in conjunction with the accompanying drawings in which:

FIG. 1 is a transmission electron microscopy (TEM) cross section showing oxidation of silicon nitride during a standard oxidation process.

FIG. 2 is a TEM cross section showing oxidation of silicon nitride during the in-situ steam generation process.

FIG. 3 is an electron energy loss spectroscopy (EELS) spectra of the oxidized layer on the side of the pad nitride shown in FIG. 2.

FIGS. 4(a) and 4(b) shows Auger depth profiles for thickness calibration.

FIGS. 5(a)-5(d) show Auger depth profiles of oxidized nitride films.

FIG. 6 shows oxidation thickness as a function of oxidation time.

FIGS. 7(a)-7(e) show in cross section a process in accordance with the oxide hard mask embodiment.

FIGS. 8(a)-8(c) show in cross section a process in accordance with an embodiment for the stripping of thin silicon nitride films in oxide-etching solution.

FIGS. 9(a)-9(c) show in cross section a process in accordance with an embodiment for the fabrication of a nitride-oxide on-chip dielectric capacitor.

FIGS. 10(a)-10(c) show in cross section a process in accordance with an embodiment for the fabrication of a oxide/nitride/oxide on-chip dielectric capacitor.

### DETAILED DESCRIPTION OF THE INVENTION

The purposes of the present invention have been achieved by providing, according to the present invention, a method to continuously convert a stable silicon nitride film into a stable silicon oxide film with a low content of residual nitrogen in the resulting silicon oxide film.

It is well known in the art that during the standard oxidation of silicon wafers having a silicon nitride layer only a small surface layer of silicon nitride undergoes a conversion to a silicon oxide film. An example of silicon nitride oxidation during a standard oxidation process is illustrated in FIG. 1.

Referring to FIG. 1 there is shown a TEM photograph of a cross section of a microstructure where a thick silicon oxide layer 10, approximately 200 Å, was grown on a silicon wall 11 in a standard oxidation furnace containing dry oxygen at a pressure of 1 ATM and at a temperature of 1000° C. The microstructure was then covered with a thin nitride liner 12 and filled with a deposited oxide 13. The contrast between the oxide 13, nitride liner 12, silicon 11, and silicon oxide layer 10 permits a determination of the thickness of the various layers.

In the upper portion of FIG. 1 a thick layer of silicon nitride 14 was exposed to the oxidation ambient. A very thin layer of oxide 15 is noticeable between the thick nitride layer 14 and the thin nitride liner 12. This is the surface oxide grown on the silicon nitride film during a standard oxidation process. The thickness of the film is less than 15 Å.

Referring now to FIG. 2 there is shown a TEM cross section of a microstructure similar to that shown in FIG. 1, but which has undergone oxidation in a ISSG reactor resulting in a thick layer of silicon oxide 20 grown from a silicon nitride film 21. The microstructure depicted in FIG. 2 resulted from an ISSG oxidation process conducted at 1050° C. for 30 seconds. A silicon oxide layer 22 100 Å thick was grown on the silicon wall 23 and 50 Å of silicon oxide 24 was provided under the silicon nitride film 21 shown in the upper portion of FIG. 2.

An EELS spectrum of the silicon oxide film 20 is shown in FIG. 3. An EELS analysis of the silicon oxide film 20 grown from the silicon nitride 21 revealed that the oxide film 20 contained a very low content of nitrogen. As shown in FIG. 3, the characteristic nitrogen peak 30 is indistinguishable from the background of the energy loss spectra. This means that the concentration of nitrogen in the oxide film is below the resolution limit of the EELS technique. The detection limit for nitrogen in this case is less than 5 atomic percent. The carbon in the spectrum is due to specimen contamination by the electron beam during analysis.

Therefore, the Applicants have discovered that the ISSG process oxidizes silicon nitride at a very fast rate which is comparable to that of the silicon oxidation. In addition, the Applicants have discovered that the oxide film grown from a silicon nitride layer has a low content of residual nitrogen. By low content of residual nitrogen it is meant that there is less than 5 atomic percent of residual nitrogen such that the silicon oxide film is substantially nitrogen free. Time of flight secondary ion mass spectroscopy (SIMS) data on silicon oxide grown on silicon nitride using standard furnace oxidation similar to that in FIG. 1 shows 20 atomic percent of nitrogen in the silicon oxide film.

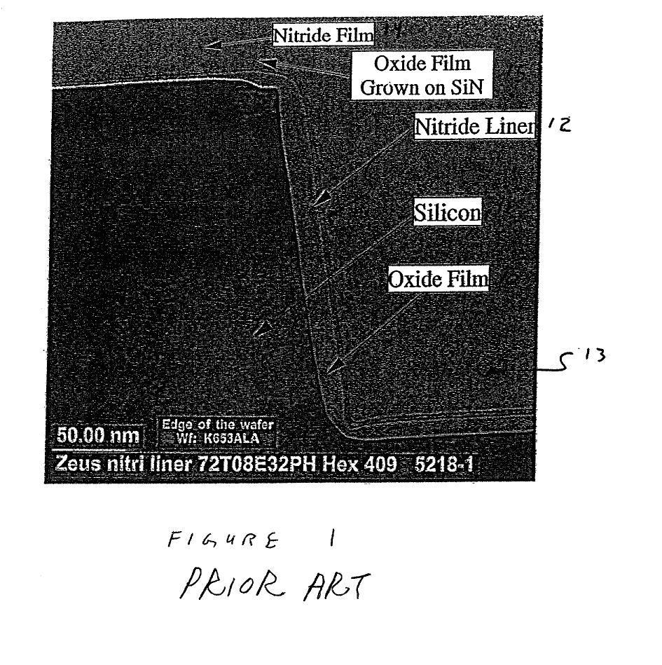

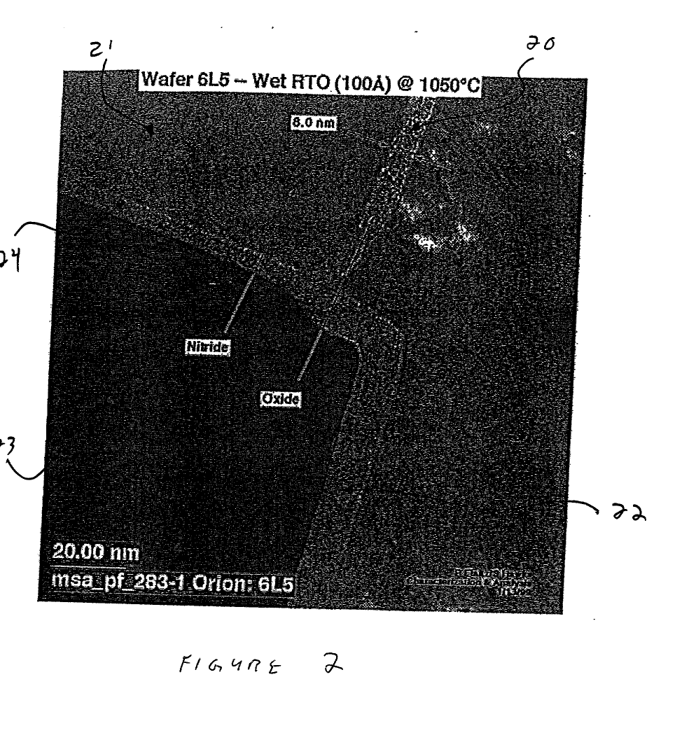

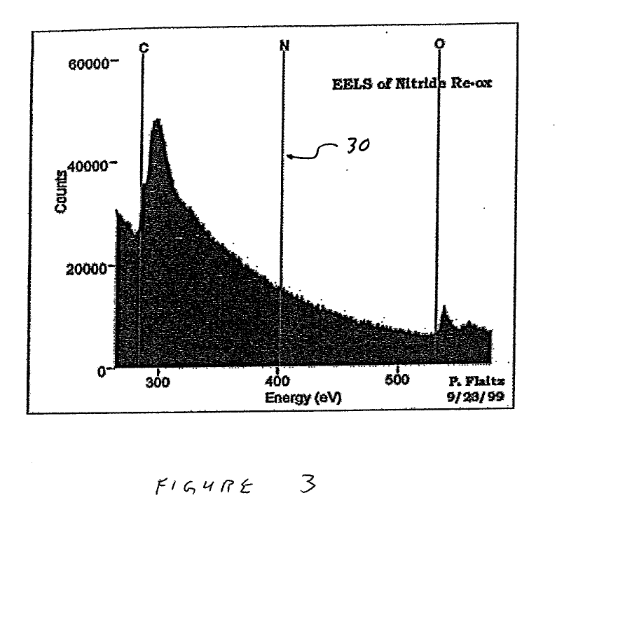

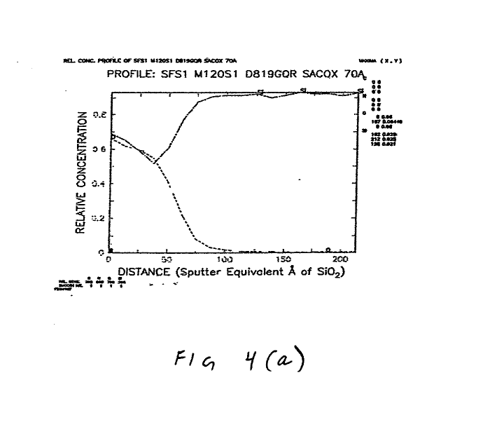

The Applicants have also investigated the oxidation of thin silicon nitride films. A thin silicon nitride film of 40 Å was first deposited on bare silicon wafers using low pressure chemical vapor deposition (LPCVD). The wafers were then oxidized in an ISSG reactor at various conditions. Their Auger electron spectra was used to determine the composition of the oxidized films. The Auger depth profile was first calibrated by creating depth profiles of a 70 Å pure oxide film and an as-grown 40 Å silicon nitride film. The 70 Å calibration depth profile in shown in FIG. 4(a) and the 40 Å calibration depth profile is shown in FIG. 4(b). In both figures the depth profile is determined from the inflection point of the lower curve representing the relative concentration of oxygen.

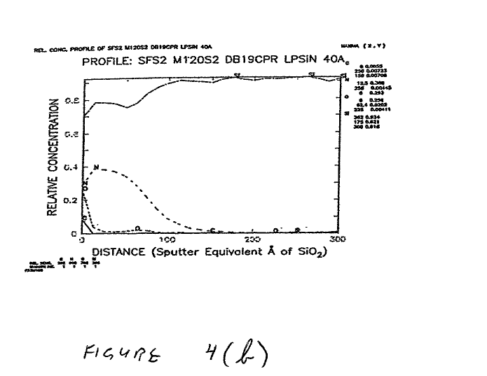

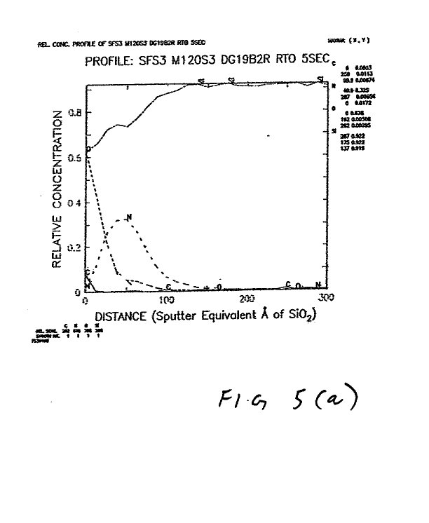

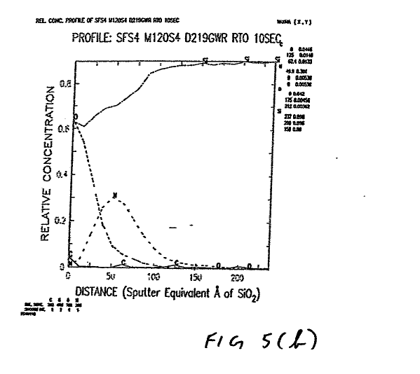

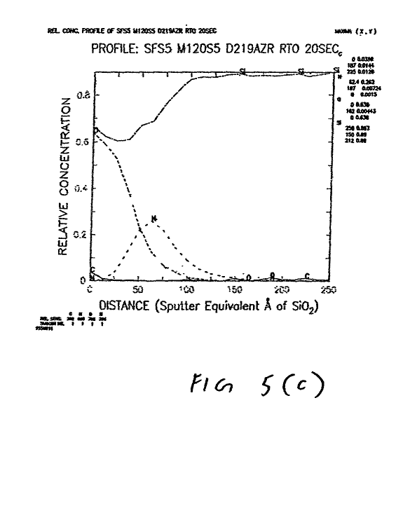

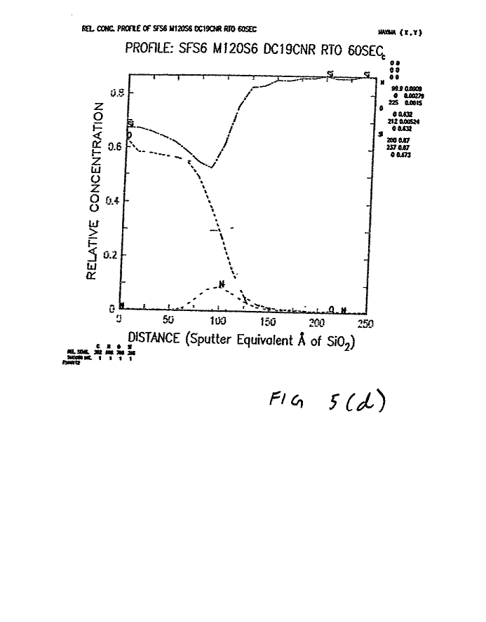

Referring to FIG. 5, the Auger depth profiles of the oxidized nitride films are shown. The oxidation parameters for the thin silicon nitride films shown in FIG. 5 are as follows: ambient 33% of H2 and 67% of O2, pressure 10 Torr, temperature 1050° C. and variable oxidation times of (a) 5 seconds, (b) 10 seconds, (c) 20 seconds and (d) 60 seconds. At the initial stages of the silicon nitride oxidation no substantial oxidation of silicon underneath the silicon nitride layer is detected. Once all or most of the silicon nitride film is converted to an oxide film, oxidation continues into the silicon.

Auger technique has a spatial resolution of about 50 Å. FIG. 5(a) shows a nitrogen signal extending all the way to the silicon oxide surface. The oxide film is only 35 Å to 40 Å thick. FIGS. 5(b) and 5(c) show a region of pure silicon oxide close to the sample surface. In FIG. 5(b) the oxide film is 50 Å thick while the oxide film of FIG. 5(c) is about 65 Å to 70 Å thick. As in FIG. 4 this is determined from the inflection point of the curve representing the relative concentration of oxygen. Only a surface portion of the auger spectra in FIGS. 5(b) and 5(c) can truly represent the chemical composition of the silicon oxide film. As shown by the strength of the auger nitrogen signal in the surface portion of the spectra in FIGS. 5(b)-5(d), the concentration of residual nitrogen in the bulk of the oxide film formed from silicon nitride using the present invention is less than the resolution limit of the auger technique. In this case, the auger technique has a resolution of about 1 atomic percent. Therefore, the present invention results in a substantially nitrogen free silicon oxide with a residual concentration of nitrogen of less than 1 atomic percent.

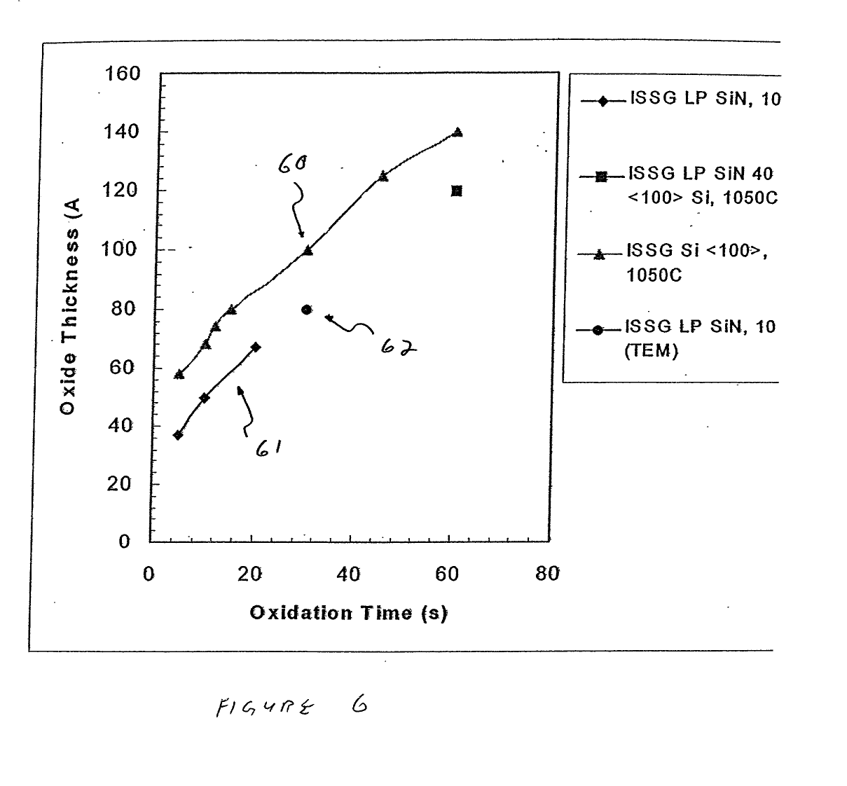

Oxide thickness as a function of oxidation time can be extracted from FIG. 5 with the aid of the calibration profiles of FIG. 4. Referring to FIG. 6 there is shown the result of this extraction. FIG. 6 shows oxidation of bare silicon 60 for comparison. The thickness of the oxide films determined from the Auger profiles 61 agrees well with that of the oxide film 62 shown in FIG. 2. The oxidation curve for silicon nitride is substantially parallel to that of the silicon. Such behavior suggests that after the growth of a thin initial layer of oxide the oxidation rates of silicon nitride and silicon are substantially the same.

Therefore a first embodiment of the invention is a method where a silicon nitride film is converted to a silicon oxide film, the method comprising the steps of: providing a silicon nitride film; providing a low pressure environment for the silicon nitride film of between about 100 Torr to about 0.1 Torr; introducing hydrogen and oxygen into the low pressure environment; maintaining the low pressure environment at a temperature of about 600° C. to about 1200° C.; wherein the hydrogen and oxygen reacts in the low pressure environment; one of the byproducts is atomic oxygen; due to the low pressure the atomic oxygen can accumulate and oxidize the silicon thereby rapidly oxidizing the silicon nitride film and converting the silicon nitride film to a silicon oxide film.

A preferred embodiment would have a pressure of 10 Torr, a temperature range of 900° C. to 1100° C. and a range of 50 to 99% oxygen and 1 to 49% hydrogen, preferably 67% oxygen and 33% hydrogen

The length of time for the conversion of the silicon nitride film to a silicon oxide film will depend on the particular furnace which is used, the amount of oxidation of the silicon nitride film that is desired and the thickness of the film. A typical time range for a single wafer tool would be 0.1 seconds to 300 seconds.

Another embodiment of the invention will be described with reference to FIGS. 7A-7E. In this masking process a silicon substrate 100 with microstructures of either planar or vertical geometry is covered with a silicon nitride film 101 as shown in FIG. 7A. The silicon substrate 100 undergoes partial oxidation of the silicon nitride film 101 as shown in FIG. 7B, where a portion of the silicon nitride film 101 is converted to a silicon oxide film 102. As shown in FIG. 7C a resist mask 103 is then deposited, patterned and developed by methods well known in the prior art. Thereafter, FIG. 7D shows a selective oxide to nitride etch is performed such that it removes the silicon oxide film 102 in the open areas. This can be accomplished using a combination of photolithography and etching, including both wet and reactive ion etching. After the resist strip the desired areas of the silicon nitride film 101 are masked by the silicon oxide film 102 thereby resulting in a hard mask silicon oxide structure 104 shown in FIG. 7E. The hard mask silicon oxide structure 104 can be used to selectively protect silicon nitride film from etching in a nitride-etching solution. The advantage of such a hard mask is that it is compatible with a high temperature process.

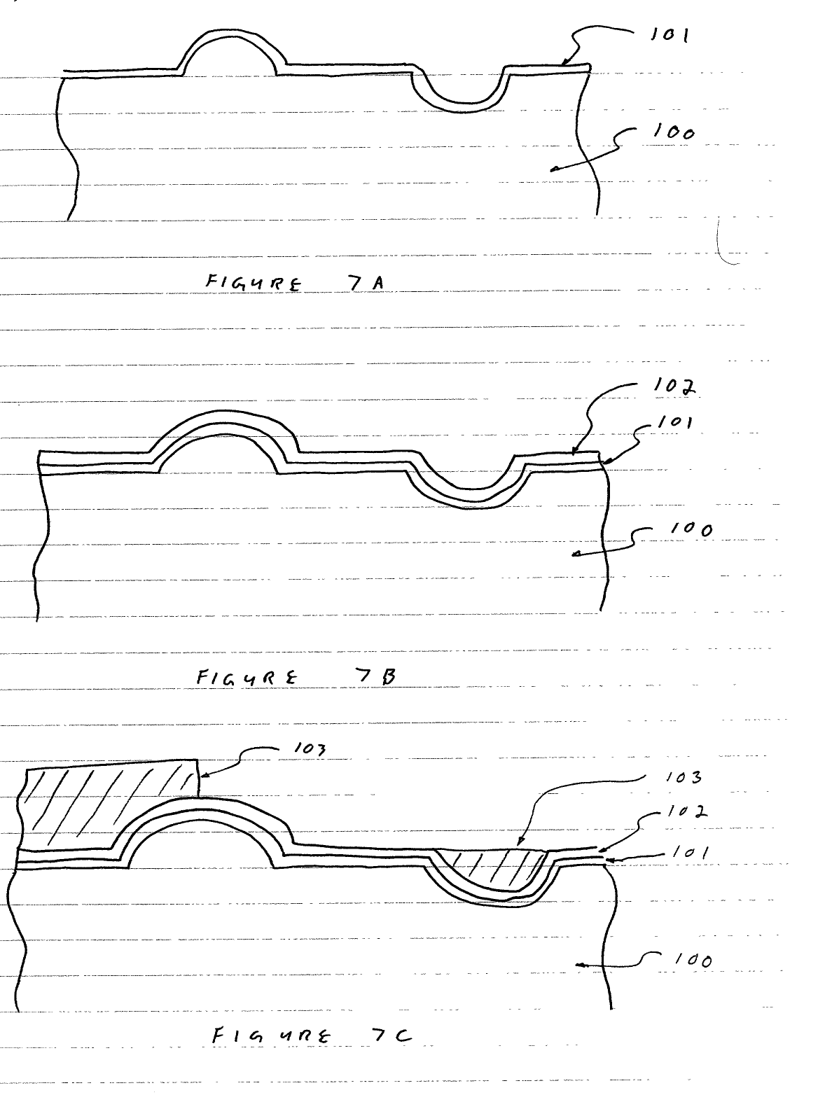

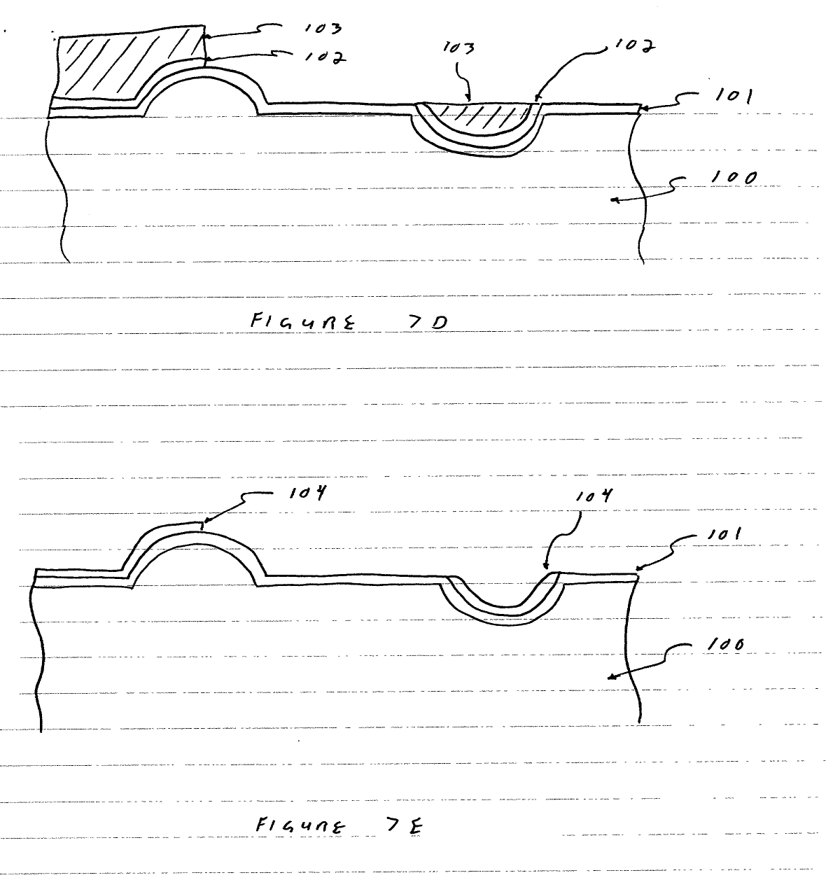

Another embodiment of the invention will be described with reference to FIGS. 8A-8C. This embodiment discloses a method of stripping a nitride layer with a wet chemistry designed for silicon oxide etching (such as HF-based solutions). Referring to FIG. 8A there is shown a silicon substrate 200 with a thin silicon nitride layer 201. If exposure of the silicon substrate 200 to a nitride-etching wet chemistry (such as hot phosphoric acid-based solution) is not desirable one can use the ISSG oxidation to first convert the thin silicon nitride layer 201 to the silicon oxide layer 202 as shown in FIG. 8B. Referring to FIG. 8C the silicon oxide layer 202 is then stripped using wet chemistry for oxide etching. (e.g., HF solution).

The present invention may be applied to oxidation through a thin layer of nitride. It is known in the prior art that if a thin nitride film is formed on a silicon surface the oxidation rates in the conventional dry, wet and steam ambient is substantially reduced. If a nitrided silicon surface is to be oxidized a silicon nitride layer must first be stripped. With the Applicants' disclosed method the stripping and cleaning step can be omitted and the nitrided silicon surface can be oxidized directly without adverse effect on the oxidation rate and quality of the oxide film.

Another application of the present invention is to dielectric on-chip capacitors, of either planar or vertical geometry, such as DRAM capacitors, and MOS transistors. As described in the cited prior art oxide/nitride/oxide and nitride/oxide dielectric stacks are used for on-chip capacitors, such as DRAM capacitors, and MOS transistors. Such structures can be easily produced with the Applicants' disclosed method.

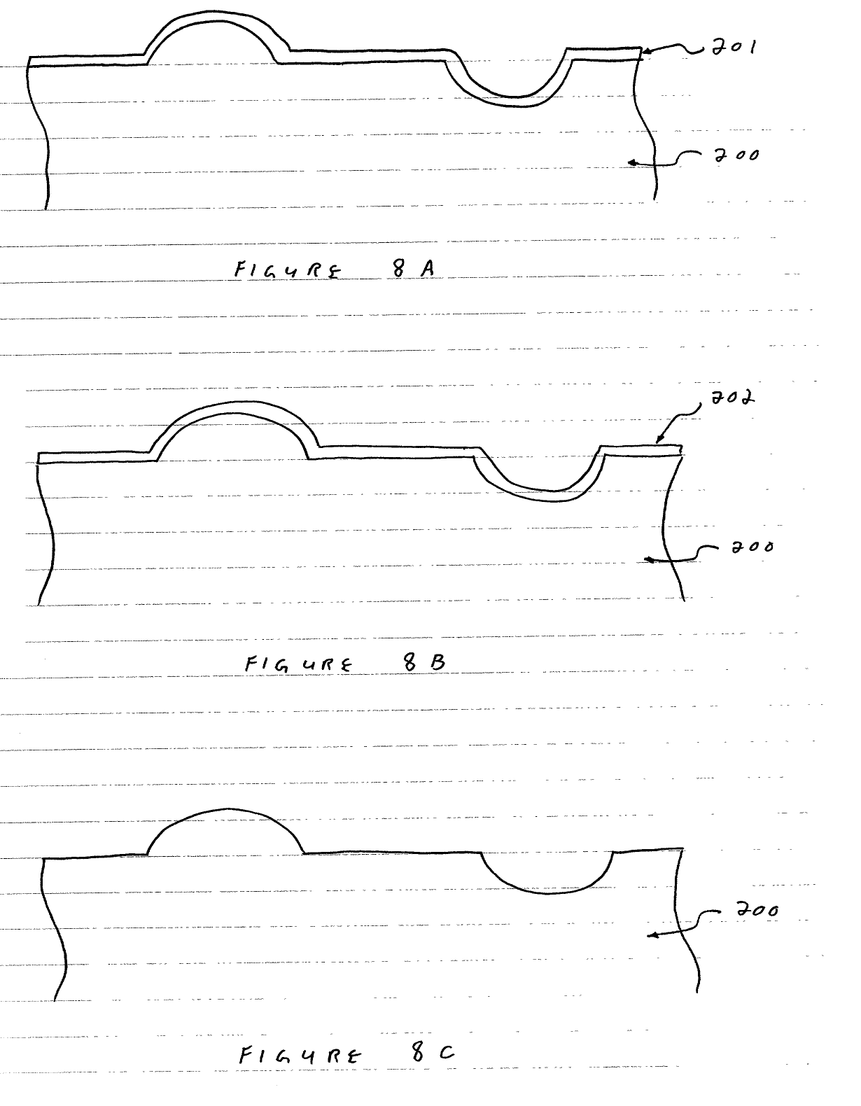

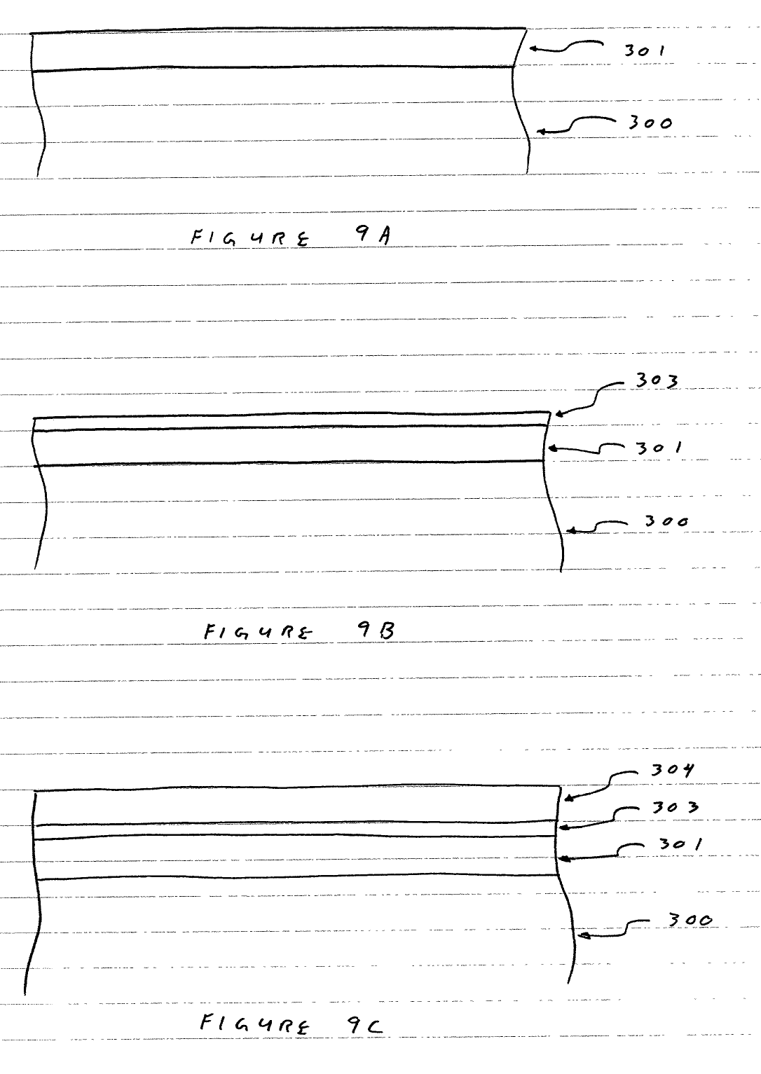

A preferred fabrication sequence for a nitride-oxide on-chip capacitor is described with reference to FIGS. 9A-9C. Referring first to FIG. 9A there is shown a first electrode 300 with a silicon nitride layer 301. Partial oxidation of the silicon nitride layer 301 using the disclosed ISSG process to produce a silicon oxide layer 303 is shown in FIG. 9B. Referring to FIG. 9C a second electrode 304 is formed on the silicon oxide layer 303 to create the final nitride/oxide on-chip capacitor.

Alternatively, it would be apparent to one skilled in the art that replacing a first electrode 300 with a semiconducting film and replacing a second electrode 304 with a conventional gate electrode will create a nitride-oxide gate dielectric of a metal insulator semiconductor field effect transistor (MISFET).

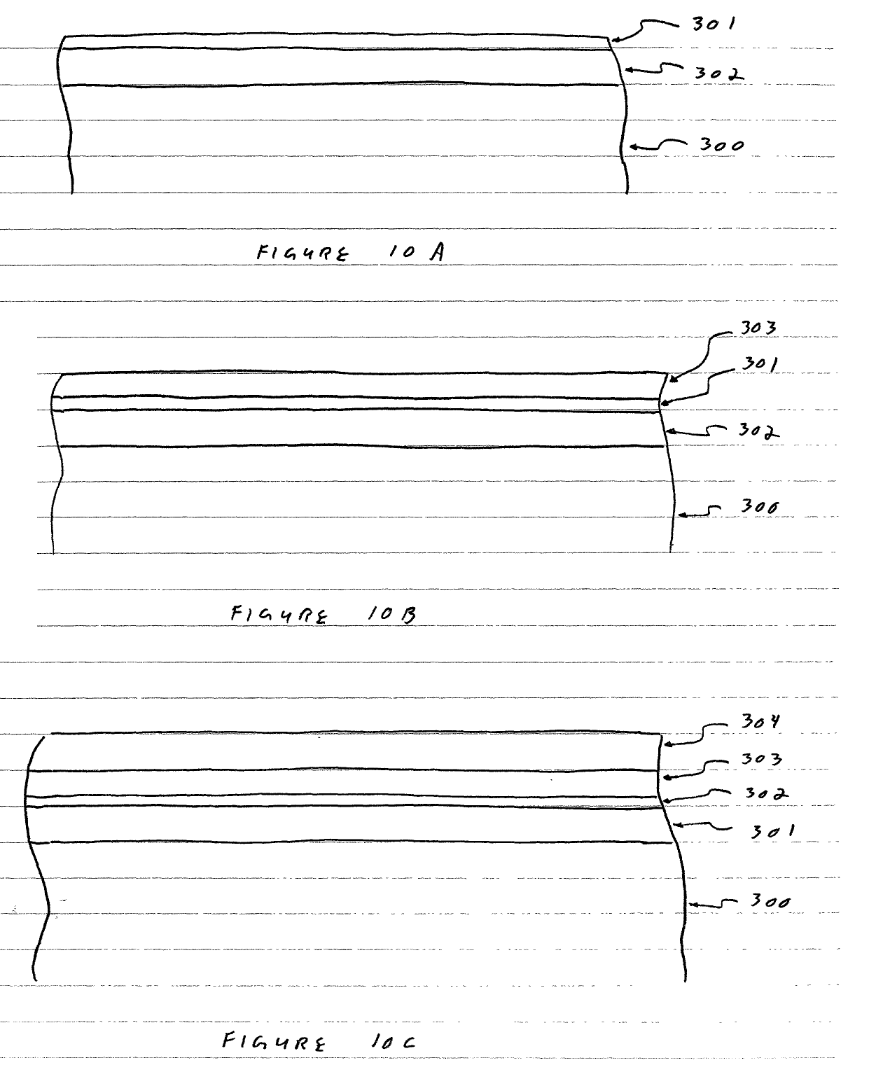

A preferred fabrication sequence for a oxide/nitride/oxide on-chip capacitor is described with reference to FIGS. 10A-10C. Referring first to FIG. 10A there is shown a first electrode 300 with a conventional silicon oxide layer 302 and a silicon nitride layer 301. Partial oxidation of the silicon nitride layer 301 using the disclosed ISSG process to produce a silicon oxide layer 303 is shown in FIG. 10B. Referring to FIG. 10C a second electrode 304 is formed on the silicon oxide layer 303 to create the final oxide/nitride/oxide on-chip dielectric capacitor.

Alternatively, it would be apparent to one skilled in the art that replacing a first electrode 301 with a semiconducting film and replacing a second electrode 304 with a conventional gate electrode will create an oxide/nitride/oxide gate dielectric of a metal insulator semiconductor field effect transistor (MISFET).

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

What is claimed is:

1. A method where a silicon nitride film is at least partially converted to a silicon oxide film, the method comprising the steps of:
providing a silicon nitride film;
providing a low pressure environment for the silicon nitride film of between about 100 Torr to about 0.1 Torf;
introducing hydrogen and oxygen into said low pressure environment;
maintaining said low pressure environment at a temperature of about 600° C. to about 1200° C. for a predetermined amount of time;
wherein said hydrogen and oxygen reacts in said low pressure environment to rapidly oxidize the silicon nitride film and convert at least partially the silicon nitride film to a silicon oxide film.

2. The method of claim 1 wherein the silicon nitride film is a continuous film.

3. The method of claim 1 wherein the silicon nitride film is a discontinuous film.

4. The method of claim 2 wherein said continuous silicon nitride film has a planar geometry.

5. The method of claim 2 wherein said continuous silicon nitride film has a vertical geometry.

6. The method of claim 3 wherein said discontinuous silicon nitride film has a planar geometry.

7. The method of claim 3 wherein said discontinuous silicon nitride film has a vertical geometry.

8. The method of claim 1 further comprising the steps of:
depositing a resist layer onto the silicon oxide film;
patterning the resist layer to form a resist mask;
etching the silicon oxide film exposed by the resist mask;
removing the resist mask to result in a hard mask silicon oxide structure.

9. A method of stripping a nitride layer with a wet chemistry designed for silicon oxide etching, the method comprising the steps of:
providing a substrate having a silicon nitride film;
providing a low pressure environment for the silicon nitride film of between about 100 Torr to about 0.1 Torr;
introducing hydrogen and oxygen into said low pressure environment;
maintaining said low pressure environment at a temperature of about 600° C. to about 1200° C. for a predetermined amount of time;
wherein said hydrogen and oxygen reacts in said low pressure environment to rapidly oxidize the silicon nitride film and at least partially convert the silicon nitride film to a silicon oxide film;
stripping the silicon oxide film with a wet chemistry designed for silicon oxide etching.

10. A method for fabricating a nitride-oxide on-chip dielectric capacitor, the method comprising the steps of:
providing a first electrode with a silicon nitride film having an exposed portion,
providing a low pressure environment for the silicon nitride film of between about 100 Torr to about 0.1 Torr;
introducing hydrogen and oxygen into said low pressure environment;
maintaining said low pressure environment at a temperature of about 600° C. to about 1200° C. for a predetermined amount of time;
wherein said hydrogen and oxygen reacts in said low pressure environment to rapidly oxidize the silicon nitride film and at least partially convert said exposed portion of the silicon nitride film to a silicon oxide film;
forming a second electrode on the silicon oxide film to create a nitride-oxide dielectric capacitor.

11. A method for fabricating an oxide/nitride/oxide on-chip dielectric capacitor, the method comprising the steps of:
providing a first electrode with a silicon oxide film on said first electrode; providing a silicon nitride film having an exposed portion on said silicon oxide film;
providing a low pressure environment for the silicon nitride film of between about 100 Torr to about 0.1 Torr;
introducing hydrogen and oxygen into said low pressure environment;
maintaining said low pressure environment at a temperature of about 600° C. to about 1200° C. for a predetermined amount of time;
wherein said hydrogen and oxygen reacts in said low pressure environment to rapidly oxidize the silicon nitride film and convert said exposed portion of the silicon nitride film to a second silicon oxide film;
forming a second electrode on the second silicon oxide film to create an oxide/nitride/oxide dielectric capacitor.

12. A method for fabricating a nitride-oxide gate dielectric of a metal insulator semiconductor field effect transistor, the method comprising the steps of:
providing a semiconducting film with a silicon nitride film having an exposed portion;
providing a low pressure environment for the silicon nitride film of between about 100 Torr to about 0.1 Torr;
introducing hydrogen and oxygen into said low pressure environment;
maintaining said low pressure environment at a temperature of about 600° C. to about 1200° C. for a predetermined amount of time;
wherein said hydrogen and oxygen reacts in said low pressure environment to rapidly oxidize the silicon nitride film and convert said exposed portion of the silicon nitride film to a silicon oxide film;
forming a gate electrode on the silicon oxide film to create a nitride-oxide gate dielectric of a metal insulator semiconductor field effect transistor.

13. A method for fabricating an oxide/nitride/oxide gate dielectric of a metal insulator semiconductor field effect transistor, the method comprising the steps of:
providing a semiconducting film having a silicon oxide film;
providing a silicon nitride film having an exposed portion on said silicon oxide film;
providing a low pressure environment for the silicon nitride film of between about 100 Torr to about 0.1 Torr;
introducing hydrogen and oxygen into said low pressure environment;
maintaining said low pressure environment at a temperature of about 600° C. to about 1200° C. for a predetermined amount of time;
wherein said hydrogen and oxygen reacts in said low pressure environment to rapidly oxidize the silicon nitride film and convert said exposed portion of the silicon nitride film to a second silicon oxide film;
forming a gate electrode on the second silicon oxide film to create an oxide/nitride/oxide gate dielectric of a metal insulator semiconductor field effect transistor.
